(19) United States
(12) Patent Application Publication
(10) Pub. No.: US 2023/0085480 A1
(43) Pub. Date: Mar. 16, 2023

(54) PERMEABLE ELEMENT

(71) Applicants: UNIVERSITÄT LINZ, Linz (AT); KOMPETENZZENTRUM HOLZ GMBH, Linz (AT)

(72) Inventors: Thomas STOCKINGER, Haag (AT); Martin KALTENBRUNNER, Linz (AT); Reinhard SCHWÖDIAUER, Linz (AT); Uwe MÜLLER, Luftenberg an der Donau (AT)

(73) Assignees: UNIVERSITÄT LINZ, Linz (AT); KOMPETENZZENTRUM HOLZ GMBH, Linz (AT)

(21) Appl. No.: 17/795,045

(22) PCT Filed: Jan. 25, 2021
(86) PCT No.: PCT/AT2021/060022

§ 371 Date: Jul. 25, 2022

(30) Foreign Application Priority Data
Jan. 27, 2020 (AT) A50062/2020

(51) Int. Cl. H05K 1/03; H05K 1/09; H05K 3/02; H01L 21/48; H01L 23/06

(52) U.S. Cl. CPC H05K 1/038; H05K 1/095; H05K 3/027; H01L 21/486; H01L 23/06; H05K 2201/0116; H05K 2201/029; H05K 2203/107

(57) ABSTRACT

The invention relates to an element in the shape of a sensor, an active electronic component, a switch, a circuit, or an electric conducting path for integration into a surrounding medium. The element is penetrable by the surrounding medium and has a porous, non-conductive substrate and at least one circuit trace made of conductive material present on the substrate. The openings of the substrate are open in an area of the circuit trace. The use and manufacture of the element are also provided.

### CROSS-REFERENCE TO RELATED APPLICATIONS

The present application is a national phase application of PCT Application No. PCT/AT2021/060022, filed Jan. 25, 2021, entitled “PERMEABLE ELEMENT”, which claims the benefit of Austrian Patent Application No. A50062/2020, filed Jan. 27, 2020, each of which is incorporated by reference in its entirety.

### BACKGROUND OF THE INVENTION

### 1. Field of the Invention

The invention relates to a penetrable element for integration into a surrounding medium, comprising at least one circuit trace on a porous, non-conductive substrate.

### 2. Description of the Related Art

US20190011288A1 relates to a sensor, onto which a circuit trace is glued as a foil or drawn using conductive ink. Drawbacks appear to include the permeability of ordinary paper, which is to be regarded as low, and the method of application, since the conductive foil and the application of the conductive ink appear to occlude the openings in the paper. Also, ink applied unilaterally will result in insufficient enclosure of the fibers and/or the circuit trace will not permanently be present on both sides of the paper.

WO2008061823A2 relates to the manufacture of a thermoelectric element. As can be best seen from FIG. 7, separated areas of a porous substrate are completely filled with semiconductor material, wherein the pores of the substrate are completely occluded by the semiconductor material, so that the substrate is no longer penetrable in the area of the semiconductor material. The electric flow is perpendicular to the surface of the substrate, i.e., from one side of the substrate to the other in the direction of the pores. As can be seen from FIG. 8, circuit traces are applied on both sides of the substrate to be connected (in series) among one another.

DE1915501A1 relates to a method of mounting a semiconductor component on a non-porous, insulating substrate. Circuit traces are first applied to the surface of the substrate, whereupon a hole is etched into the substrate, into which hole an integrated circuit is inserted.

EP 0790498 A1 relates to an electrochemical sensor, in which the working electrode and the reference electrode are separated from one another by an electric, non-conductive, permeable fabric. The non-conductive, permeable fabric does not have a circuit trace since it would short-circuit the working electrode and the reference electrode. In an embodiment of EP 0790498 A1, the reference electrode is conductive and porous, in particular by being present as a graphite foil or an otherwise conductive porous material. The reference electrode is thus completely conductive and does not have circuit traces. The electric flow runs vertically through the electrically non-conductive, permeable fabric between the working electrode and the reference electrode.

The Austrian Patent Office's search report on application A 50062/2020, giving rise to the right of priority of the present application, further lists US2017231083A1 and US5641610A as general prior art.

### SUMMARY OF THE INVENTION

The task underlying the invention is to create an electric or electronic element which can be integrated into a surrounding medium while influencing it as little as possible, in particular with regard to conversion and curing processes as well as mechanical and/or chemical stability.

To achieve said task, an element according to the claims is proposed as well as a method for manufacturing such an element and the use of said element.

The element comprises a non-conductive substrate, which is penetrable by a surrounding medium. The substrate is preferably present as a thin, planar film, for example, in the shape of a sheet or strip.

By a penetrable substrate is meant a substrate which has openings which extend from one side of the substrate to the other.

The penetrable substrate may be a woven fabric, a non-woven fabric, a fibrous mat, or an open-cell foam or sponge. Less preferably, the material may first be prepared as a dense layer and subsequently made into a penetrable substrate by perforations. For example, a foil may be made into a penetrable substrate by perforations.

In particular, the penetrable substrate may be made off of paper, textile, glass fibers, mineral fibers, or non-conductive plastic.

The circuit trace is formed by conductive material which is applied to the penetrable substrate.

The circuit trace runs in plane of the substrate, i.e., parallel to its two planar sides.

During use, the electric flow runs in the circuit trace in plane of the substrate, i.e., parallel to its planar sides. This is a difference between the present invention and the prior art, in which the electric flow is perpendicular to the planar side of, and through, the substrate.

Preferably, the penetrable substrate continues to be penetrable in the area of the circuit trace, which means that the conductive material does not occlude the openings of the penetrable substrate.

The conductive material is present on at least one side of the substrate.

Preferably, the conductive material encloses the material of the substrate entirely in the area of the circuit traces. This means that the material of the circuit traces is present on both sides of the substrate, the material of the circuit traces on the two sides being connected to one another through the openings of the substrate.

In other words, it is preferable for the material of the circuit trace to entirely enclose the material of the substrate, which is present between two adjoining openings of the substrate. Preferably, openings of the substrate which are present at the locations of the traces are not occluded by the material of the circuit trace and continue to remain.

In the case of a woven or non-woven fabric, for example, this means that the fibers of the woven or non-woven fabric in the area of the circuit traces are entirely enclosed by the material of the circuit traces and that at least some of the openings between the enclosed fibers in the area of the circuit traces are not occluded.

To manufacture the penetrable element, it is proposed to apply the material of the circuit trace to an already penetrable substrate. The material of the circuit trace may be applied on one side or on both sides of the substrate.

Preferably, the openings of the substrate are not occluded in this case.

Application of the material of the circuit traces to the substrate is preferably done by vapor-deposition with conductive material, in particular by vacuum deposition. The vapor deposition can be done by through a mask in order to apply predefined surfaces or traces of the circuit trace already.

Preferably, however, material for the circuit traces is applied planarly in a first method step and said material is removed in a targeted manner in a second step in order to form circuit traces out of the planar application. The planar application covers the entire surface of the substrate or entirely covers one or more partial surfaces thereof.

Preferably, in a first step, conductive material is planarly applied, in particular vapor deposited, to the substrate without occluding the openings of the substrate.

Preferably, in the first step, conductive material is planarly applied, in particular vapor deposited, to the substrate from both sides without occluding the openings of the substrate. The application may in the first step be done in two runs with turning the substrate in between. This may ensure that the material of the substrate, which is present between the openings, is enclosed by the conductive material on both sides and preferably entirely.

The application may also be done on both sides in one step, for example, if the substrate is not resting on a surface but is stretched in space. Also, the conductive material may be applied to a trace of the substrate, for example, a paper web, which is moved through the device which applies the conductive material.

The preferred application of the conductive material on both sides improves conductivity, allowing the use of smaller layer thicknesses of the conductive layer. Alternatively, or additionally, it can reduce the width of the circuit trace.

However, application on one side, in particular by vapor-deposition, is also possible.

After the first step, the substrate is preferably provided with conductive material in a two-dimensional area, with the openings of the substrate still open in the area provided with conductive material. The conductive material is preferably present on both sides of the substrate, with the two sides being connected through the openings of the substrate in a conductive manner

In the second step, the conductive material is removed from the substrate according to the circuit trace or traces to be prepared. This is done without destroying the substrate. As a result, the substrate remains present in the area between the circuit traces after the second step.

In a preferred embodiment according to the invention, it is proposed to remove the conductive material by laser ablation. It was surprisingly found that laser ablation on one side of the substrate is sufficient to remove the conductive material from both sides of the substrate. The material of the substrate is not destroyed in the process. Removal by laser on one side is advantageous in that turning and orienting the substrate can be omitted, which is advantageous in particular with very fine circuit trace structures or small gaps between the circuit traces.

Laser ablation is advantageous in that very fine structures may be prepared, which appears not to be possible with other methods.

Removal of the material may less preferably also be done by lithographic methods.

While application of the circuit traces using masks (for example, vapor deposition through a mask) or removal of conductive material by means of masks (etching through a mask) is basically possible, they result in less fine structures than with the preferred method of laser ablation. Also, it is disadvantageous that an individual mask is needed for each conductive structure to be prepared. Moreover, a mask is required on both sides of the substrate for application or removal on both sides, so that the masks need to be very precisely oriented with respect to one another or, when using a single mask, the substrate must be very precisely repositioned after turning.

Preferably, the conductive material is applied to the substrate in a gaseous state or as plasma.

In a less preferred embodiment, planar coating of the substrate is performed with a conductive material in a liquid state, whereupon the circuit trace is shaped by removing the material.

In an embodiment, the conductive material is sprayed on. The sprayed-on conductive material cures on the substrate. The curing can be by drying, which may be supported and/or accelerated by drying devices such as fans and/or heating devices. Preferably, the application is planar, and the formation of the circuit traces is preferably done by removing the conductive material of the planar application.

In a less preferred embodiment, the substrate may already be formed out of fibers or threads enclosed by conductive material, for example, by spinning or weaving those into a non-woven or woven fabric, wherein the circuit traces are formed after shaping the non-woven or woven fabric by removing the conductive material in a targeted manner, preferably by laser ablation.

Elements according to the invention in the shape of sensors may be used for measuring temperature, changes in density, mechanical deformations (pressure, elongation, compression, bending), changes in chemical state (e.g., curing of adhesives), moisture, penetration of liquids, pH value, biological growth processes, concentration of biomolecules, destruction or crack formation.

Contacting the circuit traces on the substrate may be done by soldering electric leads directly onto the circuit trace. A clamp may be placed on a circuit trace on both sides of the substrate. A conductive material may be glued to the circuit trace. A coil, antenna or RFID circuit may also be provided on the substrate. If the sensor is integrated into the surrounding medium in use, outward communication out of the surrounding medium may be by wireless transmission, in particular near-field communication. In an embodiment, the substrate may protrude from the surrounding medium with interfaces of the circuit traces, so that the circuit traces are directly contactable. In an embodiment, the sensor with conductors directly attached thereto, in particular cables, is integrated into the surrounding medium, with the conductors protruding from the surrounding medium. The sensor may have a power source or be preferably formed as a passive electric element.

The substrate and/or the circuit traces may be provided with reactive surfaces, for example, in order to be able to measure a pH value or light.

Changes in the electric properties of the surrounding medium can be captured with high sensitivity by two separate electrodes in an interlaced or meshing comb structure of their circuit traces.

Temperature change and/or elongation may be measured using simple conductors or individual circuit traces with interfaces on both ends.

Thermocouples may be set up using two intersecting circuit traces made of different metals—e.g. nickel-chrome/nickel (type K). This takes advantage of two circuit traces made of different metals having a thermoelectric effect at their contact surface.

Preferred uses of the permeable sensor include measuring during curing processes (concrete, adhesive, silicone, lacquer, etc.) and the continuous monitoring of components (changes in mechanical/chemical structures, humidity).

In addition, the sensor is also suitable for monitoring moisture in hygiene products, wound monitoring in medicine, soil parameters in agriculture/plants or growth/depletion of material in bioengineering processes.

In an embodiment, the permeable sensor, or the setup according to the invention, may also be used to heat the surroundings by an electrical flow in the circuit traces. For example, this may be used to allow adhesives or curable resins such as epoxy resins to cure or post-cure faster at certain points.

Preferably, the substrate of the element is a very loose cellulose fiber mat. Preferably, the element is inserted into an adhesive joint, in particular a glue joint of a wood bonding, as long as the glue is liquid or before the components are pressed together. The curing of the adhesive, in particular the glue, and its temperature may be monitored during curing. After curing, the element remains in the adhesive, or glue, joint and may detect or measure potential changes in humidity, structural integrity, or temperature (structural health monitoring).

The present element may also be employed under a veneer layer of an object, such as a piece of furniture. Preferably, in this case, the element may be formed as a temperature, pressure, or proximity sensor to detect any contact with the veneer surface. The particularly planar and permeable setup of the element prevents bulging of the veneer and visible impairment to veneer adhesion.

The present element may also be employed under a coating layer or a plaster, paint, or lacquer layer while avoiding compromising the adhesion of the respective coating, plaster, paint, or lacquer.

The material of the substrate is preferably plastic, in particular synthetic fibers, or natural material such as, in particular, glass or mineral fibers, plant fibers, cellulose, or cotton.

Preferably, the substrate is at most 2000 μm, particularly preferably at most 500 μm, in particular at most 50 μm, thick.

Preferably, the substrate has a porosity of at least 10%, particularly preferably at least 50%, in particular at least 75%.

Preferably, the substrate has an average pore size of at least 1 μm, particularly preferably at least 10 μm, in particular at least 100 μm.

Preferably, the element, in the area of the circuit trace or the conductive material, has an average porosity of at least half the porosity of the substrate.

Preferably, the element, in the area of the circuit trace or the conductive material, has an average pore size of at least half the pore size of the substrate.

The material of the circuit traces is preferably a conductive material, in particular aluminum, copper, silver, or gold, with copper being particularly preferred. Also, carbon black and conductive polymers may be used.

Preferably, the material of the circuit traces is present in a layer thickness of at most 30% of the average pore size, particularly preferably at most 10%, in particular at most 1%.

In another embodiment, a permeable element may be realized by weaving conductive fibers into a non-conductive woven fabric such that a conductive pattern results. In another embodiment, a permeable element may be realized by gluing conductive fibers into a fiber mat with the respective pattern.

Preferably, conductive fibers may in both cases be of non-conductive material which is sheathed by conductive material. A circuit or circuit trace may be shaped out of the conductive pattern by removing the conductive material from the fibers. Preferably, the non-conductive fibers are maintained when removing the conductive material.

In an embodiment, the substrate, in particular in the shape of a fiber batt, a woven or non-woven fabric, be made up of fibers entirely, which fibers have a core out of non-conductive material and a sheath out of conductive material. A circuit or circuit trace may be shaped by removing the conductive material from the fibers. Preferably, the non-conductive fibers are maintained when removing the conductive material therefrom.

In an embodiment, the porosity may be chosen such that the sensor appears generally transparent and may therefore fit well into visually appealing surroundings.

The average transmittance of the element is preferably at least 10%, in particular at least 20%, particularly preferably at least 50%, in particular at least 75%.

The high transmission is preferably achieved by the porosity, which means that the material (e.g., the fibers) of the substrate is not transparent and/or the material of the circuit traces is not transparent.

In an embodiment, the porosity of the substrate already provided with conductive material or the element already provided with circuit traces may be enhanced by perforating it. The perforation may be by mechanical, by laser, or by electric perforation. This perforation may be in the area of the circuit traces and/or in the area between the circuit traces. Preferably, the perforation is independent of the position of the circuit traces. That is, the perforations are preferably made both in the area of the circuit traces and in the area next to the circuit traces, for example by making irregularly or stochastically distributed perforations or by making a regular perforation pattern. The perforation pattern may be executed in a uniform manner for several present elements which differ in the arrangement of their circuit traces.

Less preferably, it is also possible to provide a non-porous circuit trace with the above perforations. Less preferably, it is also possible to provide a non-porous substrate both in the area of the applied circuit traces and in the area of the circuit traces with above perforations. A non-porous substrate is disadvantageous in that the material of the circuit traces can penetrate less deeply into the structure of the substrate. Also, the subsequent perforation is disadvantageous in that the conductive material is also removed, so that it does not extend into the subsequently prepared pores.

Thus, preferably, an already porous substrate is used as a starting material, to which the conductive material of the circuit traces is subsequently applied. The starting material of the porous substrate may be porous based on its structure or have already been provided with perforations prior to applying the conductive material. The conductive material may be applied to the area of the pores as well and preferably does not occlude them when being applied.

The advantages of the present permeable element include that:
it can be penetrated, resulting in less interference with the surrounding processes and material properties (no mechanical imperfection in the cured adhesive or concrete);
penetrating the element increases the sensitivity of the measurement;
simple integration into the surrounding medium;
can remain in the surrounding medium;
the porous structure makes the element lighter and requires less material.

The invention comprises the use of the element according to the invention in a surrounding medium, the element being penetrated by said surrounding medium when it is prepared or used.

In an embodiment, the surrounding medium is electrically conductive, albeit less conductive than the conductive material of the circuit trace.

In an embodiment, the surrounding medium is electrically non-conductive.

In an embodiment, the surrounding medium is curing, with the surrounding medium being electrically conductive in a non-cured state and electrically non-conductive in a cured state. In other words, the not completely cured surrounding medium contains a conductive solvent and/or water.

In an embodiment, the electric conductivity of the surrounding medium depends on its humidity. Preferably, the surrounding medium is electrically non-conductive in its dry state.

In an embodiment, the surrounding medium is a curing medium which is present in a flowable or pulpy form when being prepared or used. The element becomes enclosed by the surrounding medium due to curing. The curing of the surrounding medium is done through the openings or pores of the element, so that the cured surrounding medium extends through the openings of the element. The areas of the cured surrounding medium abutting on the two planes of the element are thus firmly connected through the openings of the element. Preferably, the surrounding medium extends through openings or pores which are present in the area of the circuit traces and the opening surface of which is at least on one side entirely surrounded by the circuit trace. Preferably, the surrounding medium extends through openings or pores which are present in the area of the circuit traces and the inner sheath surface of which is entirely sheathed by the conductive material of the circuit trace.

In an embodiment, the element is inserted in an adhesive or glue joint of components, with the surrounding medium being an adhesive or glue.

In an embodiment, the element is present beneath a veneer layer, beneath a layer of a plywood or multiplex board, or in the material of a particle board or a fiber-reinforced plastic (FRP).

In an embodiment, the element is integrated into a surrounding medium applied to a surface, in that the element was previously placed on the surface or was placed in the surrounding medium while it was applied and the surrounding medium then cured on the surface. The surrounding medium may be selected from: coating applied as a liquid; paint; lacquer; concrete; screed; plaster; and mortar.

In embodiments, the element is used for one or more of the following uses: delivering measurement values on the curing process of the surrounding medium; influencing the curing process of the surrounding medium; for detecting or measuring changes in the surrounding medium after the curing of the surrounding medium; detecting or measuring changes on, or in the vicinity of, a surface of the surrounding medium after the curing of the surrounding medium; directing an electric flow to a surface of the surrounding medium or to an electronic component enclosed in the surrounding medium; directing an electric flow beneath the surface of the cured surrounding medium.

The present invention comprises the components, parts, and objects resulting from the indicated uses.

In particular, the invention also comprises the surrounding media or objects described herein with the elements described herein that are enclosed therein. In particular, the invention also comprises the objects described herein, which have an element described herein in an adhesive or glue joint.

### BRIEF DESCRIPTION OF THE DRAWINGS

The invention is illustrated based on drawings:

FIG. 1: illustrates schematically a particularly preferred method of manufacturing a permeable element.

FIG. 2: illustrates schematically the setup of a first embodiment of a permeable element according to the invention.

FIG. 3: illustrates schematically the setup of a second embodiment of a permeable element according to the invention.

FIG. 4: illustrates schematically the setup of a third embodiment of a permeable element according to the invention.

FIG. 5: illustrates schematically the setup of a fourth embodiment of a permeable element according to the invention.

FIG. 6: illustrates a first preferred use of an element according to the invention.

FIG. 7: illustrates a second preferred use of an element according to the invention.

### DETAILED DESCRIPTION

The embodiments shown in the Figures merely show potential embodiments, that is to say the invention is not limited to those specifically shown embodiments thereof, but that combinations of individual embodiments among one another and a combination of an embodiment with the overall description provided above are also possible. These further potential combinations do not require explicit mentioning, since these further potential combinations are within the skill of those in the art based on the technical information given by the present invention.

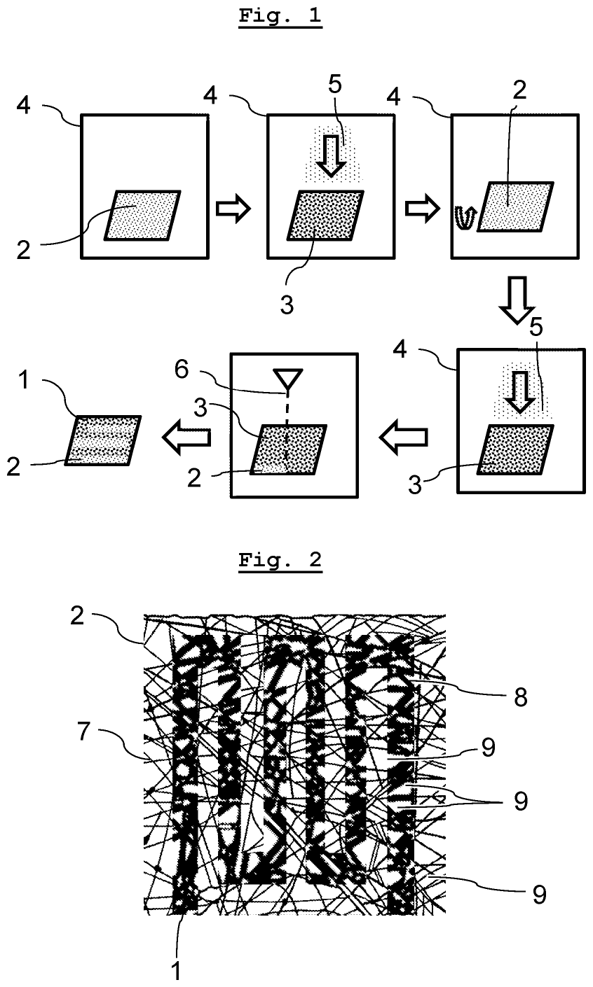

FIG. 1 shows a preferred method for manufacturing at least one circuit trace 1 on a permeable substrate 2 by applying a conductive material 3.

The starting material is a permeable substrate 2.

In the first step, the permeable substrate 2 is planarly provided with conductive material 3 in a device 4 for applying the conductive material 3. As shown, a sheet or strip of the permeable substrate 2 can be inserted into the device 4 and first be provided from one side with the conductive material 3, whereupon the substrate 2 is turned and provided with the conductive material 3 from the other side. This is preferably done be exposing the substrate 2 to a vapor 5 or plasma, so that a conductive layer is deposited around the structure of the permeable substrate 2.

In the second step, the conductive material 3 is removed from the substrate 2 to form one or more circuit traces 1. This is preferably done by guiding a laser beam 6 over the substrate 2 and subliming the conductive material 3. Removal of the conductive material 3 is preferably done by laser irradiation from one side.

The element manufactured according to this method has a permeable substrate 2, on which at least one circuit trace 1 is present. The circuit trace 1 as such is also permeable. The conductive material 3 of the circuit trace 1 encloses or sheathes the structure of the substrate 2.

FIG. 2 illustrates an element according to the invention, which can be employed, among other things, as a temperature sensor. A single circuit trace 1 is arranged in a meandering pattern on the permeable substrate 2. This allows increasing the lengths of the circuit trace 1 when little planar space is required. Measuring the resistance, or change in resistance, of the circuit trace 1 allows to derive changes in the surrounding medium of the sensors. To do so, voltage may be applied between the two ends of the circuit trace 1 and the resulting electric flow may be measured.

The substrate 2 of FIG. 2 is a non-woven fabric formed out of fibers 7. The fibers 7 may be laid out loosely or be spun or melted. In the area of the circuit trace 1, the fibers 7 are present with a sheath 8 out of conductive material 3. Openings 9 directly connecting the two planar sides of the element are present between the fibers 7 in the area of the exposed substrate 2 and in the area of the circuit trace 1 as well as in the border area between them. Preferably, the openings 9 are large enough for a surface present under the element to remain visible through the same. Preferably, the openings 9 are macroscopically visible. Preferably, the substrate 2 is more permeable and/or has larger pores than printing paper or post-it notes. Preferably, the individual fibers 7 of the substrate 2 are macroscopically visible. Preferably, the individual fibers 7 coated with metallic material are macroscopically visible in the area of the circuit trace 1.

The substrate 2 is preferably uncoated or unsized.

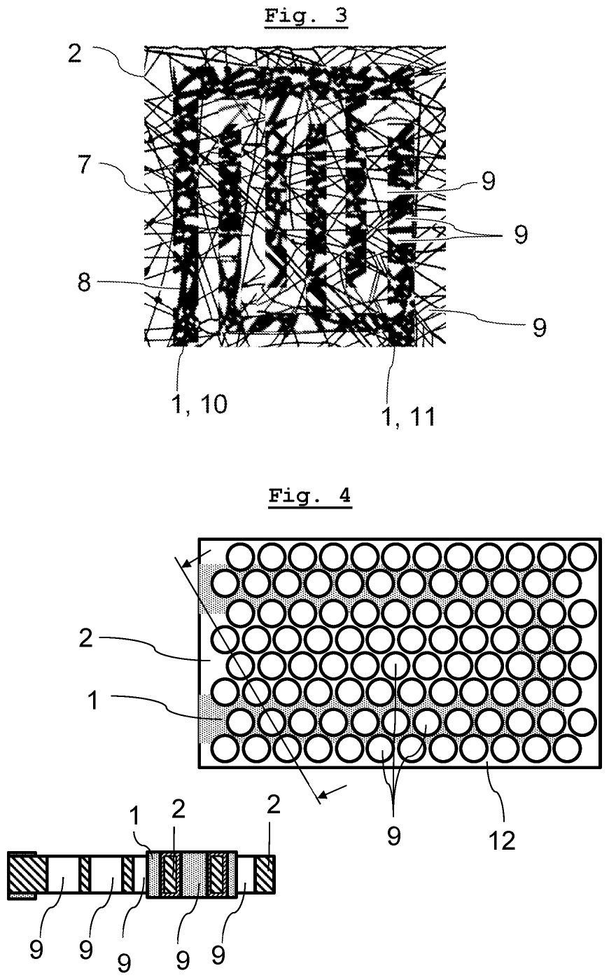

FIG. 3 illustrates an element according to the invention, where two circuit traces 1 separated from one another are attached to the substrate 2 in the shape of a first electrode 10 and a second electrode 11. Apart from the arrangement and number of the circuit traces 1, this element is equal to that of FIG. 2. The two electrodes 10, 11, for example, are each comb-shaped and interlaced. When the element according to the invention of FIG. 3 is inserted, or enclosed, in a surrounding medium, the openings 9 in the area of the uncoated substrate 2 and in the area of the circuit traces 1 are penetrated by the surrounding medium. The surrounding medium thus fills the openings 9 in the planar area of the substrate 2 between the electrodes 10, 11. A change in the surrounding medium between the electrodes 10, 11 can be measured by applying voltage between the electrodes 10 and 11 and measuring the resulting electric flow. This setup is suitable in particular for measuring curing processes in the surrounding medium.

FIG. 4 illustrates schematically the general setup of a preferred element according to the invention. The element has a thin layer of non-conductive substrate 2, which has openings or was provided with such prior to applying the circuit trace 1. The circuit trace 1 extends congruently as one path each over either of the two planar sides of the thin layer, with the two paths being connected in a conductive manner through the openings 9. As shown, openings 9 present entirely in the area of the circuit trace 1 are entirely surrounded by conductive material 3. Webs, fibers 7 or other structural elements of the substrate 2, which are present entirely in the area of the circuit trace 1, are entirely sheathed by conductive material 3, as illustrated in the sectional view of FIG. 4. The circuit trace 1 is thus not present on one side of the surface of the substrate 2 but encloses the structure of the substrate 2 through its openings 9. The circuit trace 1 encloses the permeable structure of the substrate 2 present in its area over the entire length of the circuit trace 1.

Preferably, the two paths of the circuit trace 1 are present in uniform manifestations on the opposite faces of the substrate 2, each continuously from the beginning to the end of the circuit trace 1.

Even though FIG. 4 is merely a schematic representation, the substrate 2 of the present invention can be present in this or a similar shape. What would be suitable therefore is a non-conductive foil or sheet material 12 that is in itself impermeable but has been provided with openings 9, for example in the shape of electric, laser, or mechanical perforations before the material was provided with the circuit trace 1.

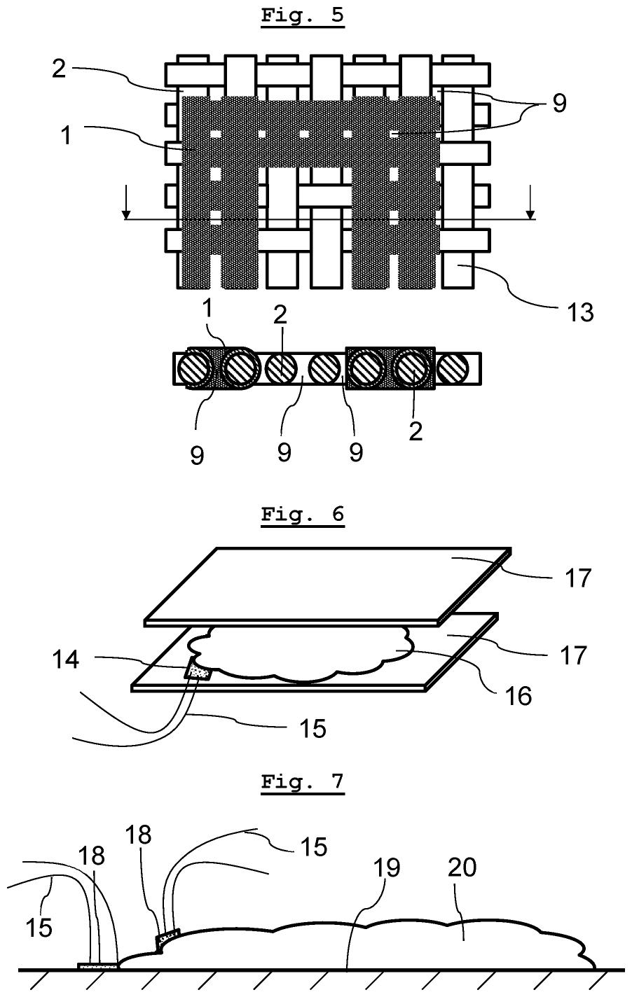

FIG. 5 illustrates the present invention with a woven fabric 13 as the substrate 2. The structural elements of the woven fabric 13 are sheathed by the conductive material 3 in the area of the circuit trace 1 such that the two congruent paths of the circuit trace 1 at the two faces of the woven fabric 13 are connected through the openings 9 between the structural elements in the area of the circuit trace 1. The structural elements may be fibers 7 or threads.

FIG. 6 illustrates a preferred use of an element according to the invention as a joint sensor 14. The sensor is placed in an adhesion or gluing face in the adhesive 16, in particular glue, between two components 17, 17, so that it is penetrated by the adhesive 16. The adhesive 16 thus penetrates the openings 9 in the substrate 2, in particular also in the area of the circuit trace 1.

FIG. 7 illustrates a preferred use of an element according to the invention as an enclosure sensor 18. The sensor is employed in a curing mass 20, so that it is enclosed in the same as it cures. The curing mass 20 is typically applied to a surface 19. The curing mass 20 can adhere to the surface 19, for example as a coating. However, the surface 19 can also be a mold or casing, so that surface 19 and the cured mass 20 can be separated from one another. The sensor, or enclosure sensor 18, can either be supported on or attached (for example glued) to the surface 19 prior to applying or introducing the mass 20 or be inserted into the mass 20 at a distance from the surface 19. In embodiments, the face of the sensor is oriented to be parallel to the surface 19 and/or parallel to a surface of the curing mass 20. The mass, or at least parts of the mass 20, penetrate the openings in the surface 2, in particular also in the area of the circuit trace 1.

In the examples of FIGS. 6 and 7, the sensors 14, 18 have contact leads 15, which protrude outside from the components 17 or the mass 20 to be contactable or readable from the outside. In another embodiment, at least part of a circuit trace 1 is a planar coil or RFID antenna to be able to transfer energy through a component 17 or the mass 20 in a contactless manner Alternatively, a conventional coil or a conventional RFID antenna, which is connected to the sensor 14, 18 in an electrically conductive manner, may be additionally provided in the mass 20 or in or between the components 17.

The element according to the invention may find use not only as a sensor but also as an active component.

The element according to the invention may, for example, be used to deliver thermal energy to the adhesive 16 or the mass 20. To do so, the element according to the invention has at least one circuit trace 1. When applying voltage, the circuit trace 1 warms up due to the electric flow. Curing of the adhesive 16 or the mass 20 is faster at higher temperatures.

Should adhesives 16 or masses 20 exist or be discovered in which the curing is initiated by electrocution or applying voltage the element according to the invention could also be used to make an adhesive 16 or mass 20 cure from the inside. In a similar manner, the element may be inserted into a combustible or explosive to make it combust or explode, respectively, from the inside due to heat development or applying voltage.

However, the element according to the invention can also be used to provide circuit traces for other electric components. In an embodiment, light-emitting materials or components such as light-emitting diodes or light-sensitive materials or components such as photosensors may be applied or attached to the element according to the invention, for example to create illumination behind a surface or veneer layer or to detect light through a surface or veneer layer.

In an embodiment, the circuit traces 1 are present on the element according to the invention as circuit traces of an electronic circuit, with the electric components being able to be present directly on the permeable substrate 2, so that they can be inserted, in particular enclosed, in a surrounding medium together. In an embodiment, the element according to the invention with the circuit traces 1 thereon is present behind the surface of a mass 20 or component 17, for example a veneer or cover layer, with holes being shaped, in particular drilled, in the surface, so that the circuit traces 1 are contactable from the outside. This allows electric components to be attached to the surface and interconnected behind the surface through the circuit traces 1.

As can be seen from FIGS. 1-7, the circuit traces 1 run in plane of the permeable substrate 2. The electric flow from a first interface on a circuit trace 1 to a second interface on a circuit trace 1 is in the direction of the plane of the permeable substrate 2. In other words, the at least one circuit trace 1 or several circuit traces 1 and the electric flow run parallel to the two largest faces of the substrate 2 opposite one another. The electric flow between two interfaces at least in portions or at least mainly runs along at least one circuit trace 1, while, preferably, circuit trace 1 does not run the shortest way between the interfaces. Preferably, two interfaces are spaced apart on the largest face of the substrate 2, with the way of the electric flow between the interfaces being longer than the distance between them.

This distinguishes the present element from the prior art, where interfaces are present on the two largest faces of the substrate 2 opposite one another, resulting in a vertical electric flow through the plane of the substrate 2 (taking the shortest way between the interfaces or electrodes).

1-20. (canceled)

21. An element comprising:
a porous, non-conductive substrate; and
at least one circuit trace made of conductive material and present on the substrate;
wherein the element is one of a sensor, an active electronic component, a switch, a circuit, and an electric conducting path for integration into a surrounding medium;
wherein the element is penetrable by the surrounding medium; and
wherein openings of the substrate are open in an area of the circuit trace.

22. The element of claim 21, wherein:
the conductive material of the circuit trace encloses a material of the substrate;
the material being present between said openings of the substrate in the area of the circuit trace; and
the material of the circuit trace is present on both sides of the substrate.

23. The element of claim 21, wherein one of:
the circuit trace is present in a meandering pattern; and
at least two circuit traces are present with meshing comb structures.

24. The element of claim 21, wherein:
the substrate has a porous structure in a shape of fibers; and
the fibers are enclosed by the conductive material of the circuit trace.

25. The element claim 21, wherein the substrate has a porous structure and the conductive material is present in a coat thickness of at most 30% of an average pore size of the substrate on the porous structure of the substrate.

26. The element of claim 21, wherein the substrate is a cellulose fiber mat consisting of loose cellulosic fibers.

27. The element of claim 21, wherein the material of the circuit trace is a vapor-deposited metal.

28. The element of claim 21, wherein the porosity of the substrate is at least 10%.

29. A method of manufacturing at least one circuit trace on a permeable substrate, comprising:
in a first step, planarly applying a conductive material to the permeable substrate, the substrate continuing to be permeable in an area of the conductive material; and
in a second step, removing the planarly applied conductive material without destroying the substrate to form at least one circuit trace out of the conductive material.

30. The method of claim 29, wherein the conductive material is applied, in the first step, in one of a gaseous state and as a plasma.

31. The method of claim 29, wherein the conductive material is removed by a laser beam in the second step.

32. The method of claim 31, wherein the laser beam is directed to the substrate from one side and the conductive material is thereby removed on both sides of the substrate.

33. The method of claim 29, wherein:
the method is used to produce an element, the element being one of a sensor, an active electronic component, a switch, a circuit, and an electric conducting path for integration into a surrounding medium;
the element is penetrable by the surrounding medium and has a porous, non-conductive substrate and at least one circuit trace made of conductive material present on the substrate; and
openings of the substrate are open in the area of the conductive material.

34. A method comprising:
arranging an element in a surrounding medium, the element being in a form of one of a sensor, an active electronic component, a switch, a circuit, and an electric conducting path;
wherein the element is penetrable by the surrounding medium and has a porous, non-conductive substrate and at least one circuit trace made of conductive material present on the substrate;
wherein openings of the substrate are open in an area of the circuit trace; and
wherein the element is penetrated by the surrounding medium during one of manufacture and use.

35. The method claim 34, wherein:
the surrounding medium is a curing medium, the curing medium being present in one of a flowable and pulpy form during one of manufacture and use; and
the element is enclosed in the surrounding medium by a curing process.

36. The method claim 34, wherein:
the element is inserted in one of an adhesive joint and a glue joint of components; and
the surrounding medium is one of an adhesive and a glue.

37. The method claim 34, wherein the element is present at one of the following:
beneath a veneer layer;
beneath a layer of one of a plywood board or a multiplex board; and
in a material of one of a particle board and a fiber-reinforced plastic.

38. The method claim 34, wherein:
the element is integrated in the surrounding medium applied to a surface;
the element has been one of:
previously placed on the surface; and
placed in the surrounding medium one of during and after applying the surrounding medium; and
the surrounding medium cures on the surface.

39. The method claim 38, wherein the surrounding medium is selected from one of the following:
coating applied as a liquid;
paint;
lacquer;
concrete;
screed;
plaster; and
mortar.

40. The method claim 34, wherein the element is used to perform at least one of the following:
delivering measurement values on a curing process of the surrounding medium;
influencing the curing process of the surrounding medium;
detecting or measuring changes in the surrounding medium after the curing process of the surrounding medium;
detecting or measuring changes on, or in the vicinity of, a surface of the surrounding medium after the curing process of the surrounding medium;
directing an electric flow to a surface of the surrounding medium or to an electronic component enclosed in the surrounding medium; and
directing an electric flow beneath the surface of the cured surrounding medium.
